(19) United States
(12) Patent Application Publication
(10) Pub. No.: US 2010/0175989 A1
(43) Pub. Date: Jul. 15, 2010

(54) DEPOSITION APPARATUS, DEPOSITION SYSTEM AND DEPOSITION METHOD

(75) Inventors: Kazuki Moyama, Hyogo (JP); Toshihisa Nozawa, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/376,635

(22) PCT Filed: Aug. 8, 2007
(86) PCT No.: PCT/JP2007/065512

§ 371 Date: Feb. 6, 2009

(30) Foreign Application Priority Data
Aug. 9, 2006 (JP) 2006-216802

(51) Int. Cl. C23C 14/34; C23C 16/00

(52) U.S. Cl. 204/192.12; 204/298.02; 204/298.07

(57) ABSTRACT

A deposition system is provided to avoid cross contamination in each layer formed in a manufacturing process of organic electroluminescent device and the like, and to reduce footprint and to enhance productivity. Provided is a deposition apparatus 13 for forming a film on a substrate G, which includes a first deposition mechanism 35 for forming a first layer in a processing chamber 30, and a second deposition mechanism 36 for forming a second layer in the processing chamber 30. The first deposition mechanism 35 includes: a nozzle 34 disposed at an inside of the processing chamber 30, for supplying vapor of a deposition material to the substrate; a vapor generator 45 disposed at an outside of the processing chamber, for generating the vapor of the deposition material; and a line for transporting the vapor of the deposition material generated from the vapor generator 45 to the nozzle 34.

### TECHNICAL FIELD

The present invention relates to a deposition apparatus and a deposition system for forming a layer of a predetermined material on a substrate, and also relates to a deposition method.

### BACKGROUND ART

In recent years, an organic electroluminescent (OEL) device has been developed utilizing electroluminescence (EL). As the organic electroluminescent (OEL) device generates almost no heat, it consumes lower power compared with a cathode-ray tube. Further, since the OEL device is a self-luminescent device, there are some other advantages, for example, a view angle wider than that of Liquid Crystal Display (LCD), so that progress thereof in the future is expected.

Most typical structure of Organic Electroluminescent device includes an anode (positive electrode) layer, a light-emitting layer and a cathode (negative electrode) layer stacked sequentially on a glass substrate to form a sandwiched shape. So as to bring out light from the light-emitting layer, a transparent electrode made of Indium Tin Oxide (ITO) is used as the anode layer on the glass substrate. As to the Organic Electroluminescent device of this type, generally OEL device is manufactured by forming the light-emitting layer and the cathode layer in this order on a preformed ITO layer (anode layer) on the glass substrate.

In addition, in order to ease the electron movement from the cathode layer to the light emitting layer, there is formed a work function adjustment layer (electron transport layer) therebetween. This work function adjustment layer is formed by, for example, depositing alkali metal, such as Lithium on an interface of the light emitting layer in the cathode layer side by evaporation. A deposition apparatus shown in Patent Document 1, for example, is known as a fabricating apparatus for the above described Organic Electroluminescent device.

### Patent Document 1: Japanese Patent Laid-open Publication No. 2004-79904

### DISCLOSURE OF THE INVENTION

### Problems to Be Solved by the Invention

In an Organic Electroluminescent device manufacturing process, although a film forming process such as an evaporation method or a Chemical Vapor Deposition process is performed to form each layer, cross-contamination arising from each layer formation process should be somehow avoided. Here, to avoid this undesirable intermix, deposition apparatuses for each layer of the organic EL device are disposed in different processing chambers.

However, the deposition system size becomes larger and the footprint of whole deposition system is increased if an independent processing chamber is adopted for every deposition mechanism. Further, the substrate to be processed is transferred from the processing chamber to the subsequent processing chamber every time the process is completed, thus resulting in an increase of carry in/out steps. Therefore, throughput can be limited. Furthermore, for example, alkali metal constituting a work function adjustment layer is highly active so that it is apt to react with moisture, nitrogen, oxygen or the like remaining in the processing chamber and be deteriorated. Accordingly, after forming the work function adjustment layer, it is desirable to quickly form the cathode layer.

In order to solve the problem incurred when each deposition mechanism is disposed in different processing chambers, it would be good to dispose a plurality of deposition mechanisms in the same processing chamber. If so, however, there will occur the problem of cross-contamination as stated above. In particular, since the alkali metal constituting the work function adjustment layer is highly active, it has been difficult to dispose the deposition mechanism for forming the work function adjustment layer together with other deposition mechanisms in the same processing chamber.

Therefore, the object of the present invention is to avoid cross-contamination of each layer arising from each film forming process, further to provide a deposition system with reduced footprint and higher productivity.

### Means for Solving the Problems

In accordance with the present invention, there is provided a deposition apparatus for forming a film on a substrate, the apparatus including: a first deposition mechanism for forming a first layer in a processing chamber; and a second deposition mechanism for forming a second layer in the processing chamber, wherein the first deposition mechanism includes: a nozzle which is disposed at an inside of the processing chamber, for supplying vapor of a deposition material to the substrate; a vapor generator which is disposed at an outside of the processing chamber, for generating the vapor of the deposition material; and a line for transporting the vapor of the deposition material generated from the vapor generator to the nozzle.

In the deposition apparatus, the vapor generator may include: a chamber disposed at the outside of the processing chamber; and a heating device for heating a deposition material source in the chamber. Further, the vapor of the deposition material may be transported to the nozzle from the vapor generator by using a carrier gas. In this case, as the carrier gas, an inactive rare gas (e.g., Ar) or the like is used on the substrate, for example. Further, the chamber may be allowed to be opened and closed. Furthermore, it is possible that the deposition apparatus further includes: a vacuum pump for evacuating the inside of the processing chamber to a reduced pressure; a vacuum pump for evacuating an inside of the chamber to a reduced pressure; and an opening/closing mechanism for opening and closing the line. In this case, a volume of the chamber may be smaller than that of the processing chamber.

In addition, the deposition apparatus may further include: a transfer mechanism for transferring the substrate to each processing position of the first deposition mechanism and the second deposition mechanism in the processing chamber. Further, the second deposition mechanism may form the second layer by a sputtering method.

Moreover, in accordance with the present invention, there is provided a deposition system for forming a film on a substrate, the system including: a deposition apparatus as described above; and a separate deposition apparatus having a third deposition mechanism for forming a third layer in a processing chamber.

In this deposition system, there may be provided a transfer apparatus which transfers the substrate between the deposition apparatus and the separate deposition apparatus. Further, the third deposition mechanism may form the third layer on a surface of the substrate by an evaporation method.

Furthermore, in accordance with the present invention, there is provided a deposition method for forming a film on a substrate, the method including: forming a first layer by supplying vapor of a deposition material, which is generated at an outside of a processing chamber, to the substrate through a nozzle disposed at an inside of the processing chamber; and subsequently, forming a second layer at the inside of the processing chamber. Further, it is possible that the vapor of the deposition material generated at the outside of the processing chamber can be transported to the nozzle by using a carrier gas (transport gas) such as Ar or the like.

In this deposition method, the second layer may be formed by a sputtering method. Further, a third layer may be preformed at an inside of a separate processing chamber. Furthermore, the third layer may be formed by an evaporating method.

### EFFECT OF THE INVENTION

In accordance with the present invention, since the first deposition mechanism for forming the first layer and the second deposition mechanism for forming the second layer are provided in the same processing chamber, the deposition apparatus and the deposition system can be small in size. Further, throughput can be increased because the first layer and the second layer are successively formed in single processing chamber. Furthermore, for example, after forming the work function adjustment layer, it is possible to quickly form the cathode layer, thereby preventing the work function adjustment layer from being deteriorated.

In addition, in the first deposition mechanism, a vapor generator for generating the vapor of the deposition material is installed outside the processing chamber, so that the material used for the first deposition mechanism is prevented from flowing to the second deposition mechanism side, and thus the cross-contamination between the first layer and the second layer is efficiently avoided. Further, in the second deposition mechanism, the second layer is formed on the substrate surface by the sputtering process so that it is possible to achieve the scale up of the substrate size.

Moreover, the third deposition mechanism is disposed in a processing chamber and the first and second deposition mechanisms are disposed in a different processing chamber, so that the contamination to the third layer and the contamination to the first and second layers can be avoided.

### BRIEF DESCRIPTION OF THE DRAWINGS

FIG. 1 is a flow chart of an organic electroluminescent device fabrication process;

FIG. 2 is a plain view of a deposition system in accordance with an embodiment of the present invention;

FIG. 3 is an overview structure of a sputtering-evaporating apparatus;

FIG. 4A is a top view of a nozzle of an evaporating mechanism (a first deposition mechanism), FIG. 4B is a front view thereof, and FIG. 4C is a side view thereof;

FIGS. 5A and 5B are overview structures of a sputtering mechanism (a second deposition mechanism);

FIG. 6 is an overview structure of an evaporating apparatus; and

FIG. 7 is an overview structure of an evaporating mechanism (a third deposition mechanism).

### EXPLANATION OF CODES

A: organic EL device
G: substrate
M: mask
1: anode layer
2: light emitting layer (third layer)
3: work function adjustment layer (first layer)
4: cathode layer (second layer)
10: deposition system
11: transfer apparatus
12: substrate load lock mechanism
13: sputtering-evaporating apparatus
14: alignment apparatus
15: shape forming apparatus
16: mask load lock apparatus
17: CVD apparatus
18: substrate reverse apparatus
19: evaporating apparatus
20: transfer mechanism
30: processing chamber
31: exhaust line
32: vacuum pump
34: nozzle
35: evaporating mechanism (first deposition mechanism)
36: sputtering mechanism (second deposition mechanism)
40: transfer mechanism
45: vapor generator
46: line
50: chamber
51: heating mechanism
53: transport gas supply line
56: exhaust line
57: vacuum pump
58: opening/closing valve
60: target
85: evaporating mechanism (third deposition mechanism)

### BEST MODE FOR CARRYING OUT THE INVENTION

Below, embodiments of the present invention will be explained referring to the drawings. In the following embodiment, as an example of deposition, a manufacturing process for an organic electroluminescent device A which is manufactured by forming an anode (positive electrode) layer 1, a light emitting layer 2 and a cathode (negative electrode) layer 4 on a target surface (e.g., a top surface) of a glass substrate G is described in detail. In the specification and the drawings, like reference numerals denote like parts having substantially identical functions and configurations, so that redundant description thereof may be omitted.

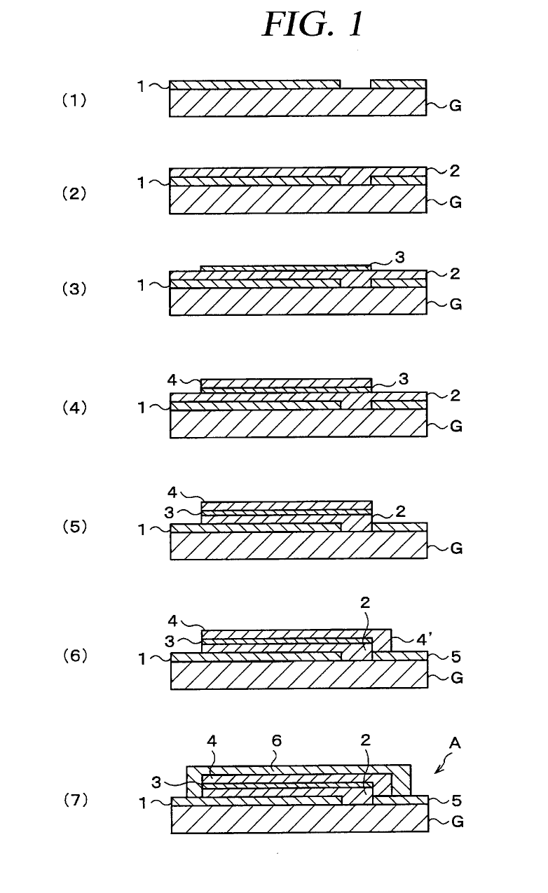

From FIGS. 1 (1) through (7), there is described the manufacturing process of the organic electroluminescent device A. As shown in FIG. 1 (1), on the surface of the glass substrate G used for this embodiment, the anode (positive electrode) layer 1 is preformed as a predetermined pattern. A transparent electrode is used for the anode layer 1 made of, for example, ITO (Indium Tin Oxide).

First of all, as described in FIG. 1 (2), the light emitting layer 2 is formed on the anode layer 1 over the glass substrate G. This light emitting layer 2 is formed by depositing, for example, aluminato-tris-8-hydroxyquinolate (Alq₃) on the surface of the glass substrate G. Before forming the light emitting layer 2, a hole transfer layer (HTL) (not shown in the figure), including, e.g., NPB (N,N-di(naphthalene-1-yl)-N,N-diphenyl-benzidene) is deposited on the anode layer 1 by evaporation, and then the light emitting layer 2 is formed on it to form a multiple stacked structure.

In the next step, as shown in FIG. 1 (3), on an interface of the light emitting layer 2, a work function adjustment layer 3 is deposited to form a predetermined shape by evaporating alkali metal such as Li. The work function adjustment layer 3 acts as an ETL (Electron Transport Layer) to ease electron transport from the cathode layer 4 (explained later) to the light emitting layer 2. Aforementioned work function adjustment layer 3 is deposited by evaporation with, e.g., alkali metal such as Li by using a pattern mask.

Subsequently, as shown in FIG. 1 (4), the cathode (negative electrode) layer 4 is patterned onto the work function adjustment layer 3. This cathode layer 4 is formed by sputtering, for example, Ag, Mg/Ag alloy using a pattern mask.

Next, as shown in FIG. 1 (5), the light emitting layer 2 is formed into a predetermined shape corresponding to that of the cathode layer 4.

Further, as shown in FIG. 1 (6), a connecting portion 4′ of the cathode layer 4 is formed so as to electrically connect it to an electrode 5. This connecting portion 4′ is also formed by sputtering, for example, Ag, Mg/Ag alloy using a pattern mask.

Finally, as described in FIG. 1 (7), a sealing film 6 including, for example, a nitride film is formed by a CVD to encapsulate a whole sandwiched-structure having the light emitting layer 2 interleaved between the cathode layer 4 and the anode layer 1, and then the organic electroluminescent device A is manufactured.

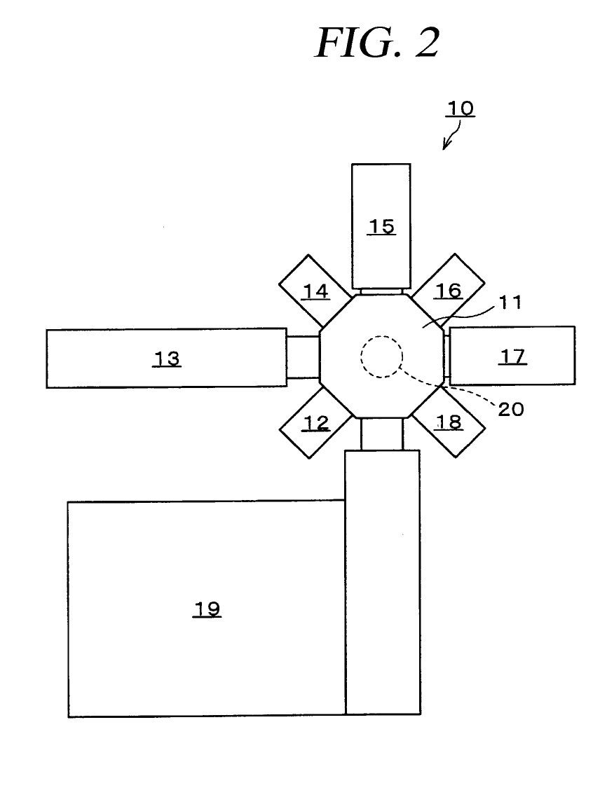

FIG. 2 shows a drawing to explain a deposition system 10 in accordance with an embodiment of the present invention. This deposition system 10 is configured to manufacture the organic electroluminescent device A as described in FIG. 1. Here, in manufacturing the device, the work function adjustment layer 3, the cathode layer 4, and the light emitting layer 2 (including, for example, the hole transport layer) are explained in detail as a first layer, a second layer, and a third layer, respectively.

In the deposition system 10, a substrate load lock apparatus 12, a sputtering-evaporating apparatus 13, an alignment apparatus 14, a shape forming apparatus 15 for the light emitting layer 2, a mask load lock apparatus 16, a CVD apparatus 17, a substrate reverse apparatus 18, and an evaporating apparatus 19 are arranged around a transfer apparatus 11. In the present invention, the sputtering-evaporating apparatus 13 is a deposition apparatus for forming the work function adjustment layer 3 as the first layer and the cathode layer 4 as the second layer. The evaporating apparatus 19 corresponds to a deposition apparatus for forming the light emitting layer 2 as the third layer.

The transfer apparatus 11 includes a transfer mechanism 20 which transfers a substrate G into/out of the apparatuses 12 through 19 independently. Therefore, the transfer apparatus 11 can transfer the substrate G among the apparatuses 12 through 19 in an arbitrary order.

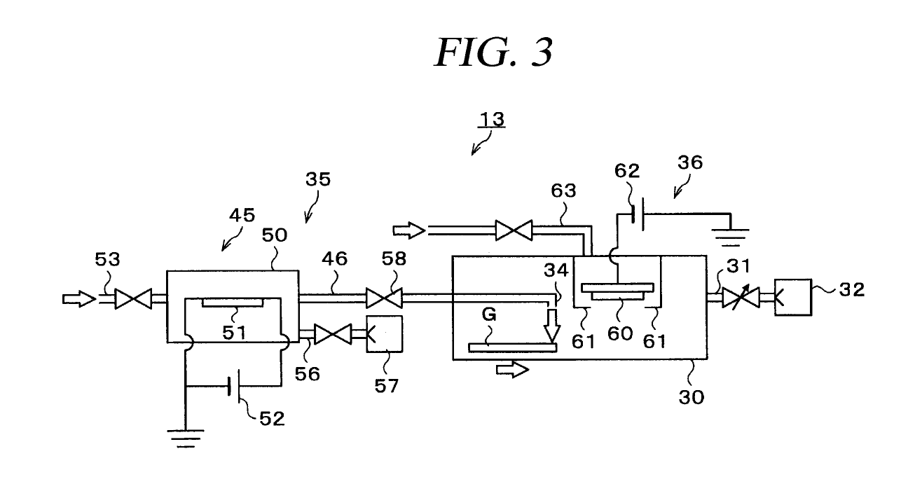

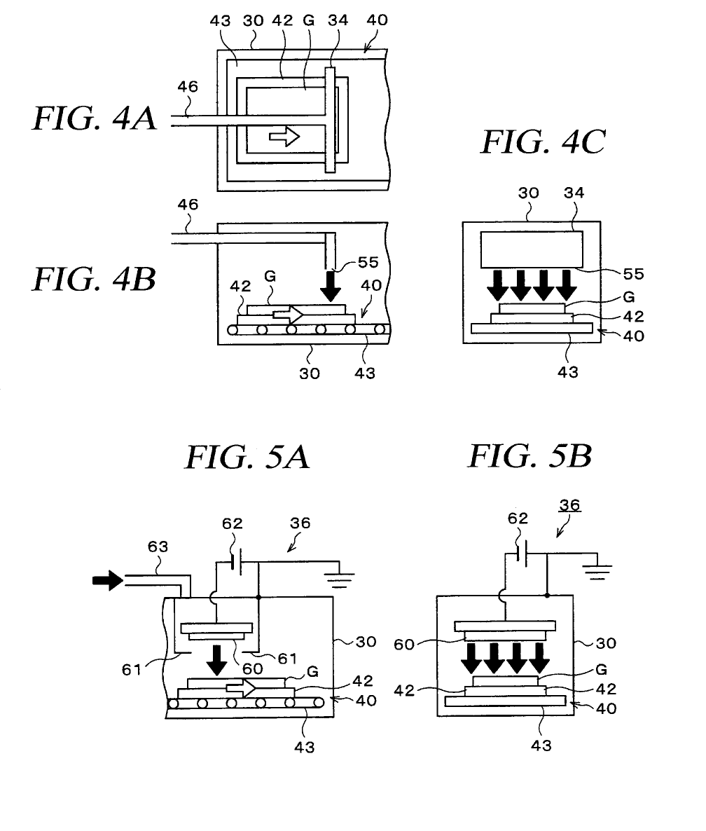

FIG. 3 schematically shows an overview drawing of the sputtering-evaporating apparatus 13 for forming the first and the second layers. FIGS. 4A through 4C are top, front and side views of a nozzle 34 of an evaporating mechanism 35 provided in the sputtering-evaporating apparatus 13. FIGS. 5A and 5B show overview drawings of a sputtering mechanism 36 provided in the sputtering-evaporating apparatus 13. In the present invention, the evaporating mechanism 35 in the sputtering-evaporating apparatus 13 corresponds to a first deposition mechanism for forming the work function adjustment layer 3 as the first layer. Further, the sputtering mechanism 36 corresponds to a second deposition mechanism for forming the cathode layer 4 as the second layer.

As shown in FIG. 3, at one side of a processing chamber 30 which constitutes the sputtering-evaporating apparatus 13, there is connected an exhaust line 31 through which inside of the processing chamber 30 is evacuated to a reduced pressure by operation of an vacuum pump 32. At one side of the processing chamber 30, there is a non-illustrated transfer opening opened or closed by a gate valve. Through the transfer opening, the substrate G is transferred into or out of the sputtering-evaporating apparatus 13 by the above-mentioned transfer mechanism 20 of the transfer apparatus 11.

Installed inside the processing chamber 30 are the nozzle 34 of the evaporating mechanism 35 serving as the first deposition mechanism and the sputtering mechanism 36 serving as the second deposition mechanism. Further, as illustrated in FIGS. 4A through 4C and FIGS. 5A and 5B, installed within the processing chamber 30 is a transfer mechanism 40 for transferring the substrate G at the positions below the evaporating mechanism 35 and the sputtering mechanism 36.

The transfer mechanism 40 includes a stage 42 for holding the substrate G and a conveyor 43 for transferring the stage 42 at the positions below the evaporating mechanism 35 and the sputtering mechanism 36. The stage 42 is formed of, for example, an electrostatic chuck to mount and hold the substrate G on the top surface thereof. Further, on the substrate G held on the stage 42, a non-illustrated mask is aligned and then held.

The substrate G and the mask are transferred into the processing chamber 30 by aforementioned transfer mechanism 20 of the transfer apparatus 11. Then the substrate G and the mask loaded into the processing chamber 30 are held to be aligned onto the top surface of the stage 42.

In the first place, the transfer mechanism 40 transfers the substrate G held on the top surface of the stage 42 to the position below the evaporating mechanism 35. Then, the work function adjustment layer 3 (first layer) is deposited by evaporation on the substrate G to form a predetermined pattern by the evaporating mechanism 35. Next, the substrate G held on the top surface of the stage 42 is transferred to the position below the sputtering mechanism 36. Then, the cathode layer 4 (second layer) is deposited by sputtering on the substrate G to form a predetermined pattern by the sputtering mechanism 36. Finally, the above-mentioned transfer mechanism 20 of the transfer apparatus 11 transfers the substrate G and the mask M out of the processing chamber 30.

As illustrated in FIG. 3, the evaporating mechanism serving as the first deposition mechanism includes the nozzle 34 disposed inside of the processing chamber 30, a vapor generator 45 disposed outside of the processing chamber 30, and a line 46 for transporting vapor of a deposition material from the vapor generator 45 to the nozzle 34.

The vapor generator 45 is configured to dispose a heating mechanism 51 within a chamber 50 installed outside of the processing chamber 30. The volume of the chamber 50 is smaller than that of the processing chamber 30.

The heating mechanism 51 has a shape of a chamber so as to accommodate therein a deposition material source for generating vapor of alkali metal such as Li or the like which is a material for the work function adjustment layer 3 serving as the first layer, and the whole body of the heating mechanism 51 is made of an electrical resistor which is heated by a voltage supplied from a power source 52. In this manner, the deposition material source accommodated in the heating mechanism 51 is heated, thereby generating the vapor of the material for the work function adjustment layer 3.

The chamber 50 is connected with a transport gas supply line 53 for supplying a transport gas containing a rare gas such as Ar or the like which is inactive with respect to the substrate G. Together with the transport gas (carrier gas, for example, rare gas such as Ar or the like) supplied to the chamber 50 through the transport gas supply line 53, the vapor of the deposition material is supplied to the nozzle 34 from the vapor generator 45 via the line 46.

At the lower surface of the nozzle 34, a slit 55 is formed to make a right angle with the transfer direction (stage 42's moving direction) of the substrate G. The length of the slit 55 is almost the same as the width of the substrate G being transferred below the nozzle 34. As stated above, together with the transport gas, the vapor of the deposition material provided from the vapor generator 45 is supplied downward from the slit 55 formed at the lower surface of the nozzle 34. Then, the alkali metal is deposited on the surface of the substrate G passing through lower side of the evaporating mechanism 35 so that the work function adjustment layer 3 is formed.

Furthermore, an exhaust line 56 is connected at a side of the chamber 50, and the inside of the chamber 50 can be evacuated to a reduced pressure through the exhaust line by operation of a vacuum pump 57. On the line 46 communicating the processing chamber 30 with the chamber 50, installed is an opening/closing valve 58 serving as an opening/closing device, and an interior atmosphere of the processing chamber 30 can be separated from that of the chamber 50 by closing the opening/closing valve 58. Moreover, it may be possible to install a shutter for opening and closing the nozzle 34 instead of the opening/closing valve 58.

Further, the chamber 50 can be opened and closed so that it can be opened when replenishing the heater 51 disposed in the chamber 50 with the deposition material source for generating the vapor of the alkali metal such as Li or the like which is the material for the work function adjustment layer 3.

As shown in FIGS. 5A and 5B, the sputtering mechanism as the second deposition mechanism includes a plate-shaped target 60 disposed horizontally with respect to the upper side of the substrate G passing through the lower side of the sputtering mechanism 36. The target 60 is made of Ag or Mg/Ag alloy, for example. A ground electrode 61 is disposed around the target 60, and voltage is applied between the target 60 and the ground electrode 61 from a power source 62. Further, outside of the ground electrode 61, a non-illustrated magnet is disposed to generate magnetic field at the lower side of the target 60. Further, between the target 60 and the ground electrode 61, a sputtering gas such as Ar gas is supplied from a sputtering gas supply line 63. While generating the magnetic field at the lower side of the target 60, glow discharge is generated between the target 60 and the ground electrode 61, and plasma is generated at the lower side of the target 60. By utilizing a sputtering phenomenon using this plasma, material of the target 60 is sputtered to be deposited onto the substrate G passing below the sputtering mechanism 36, thereby forming the cathode layer 4.

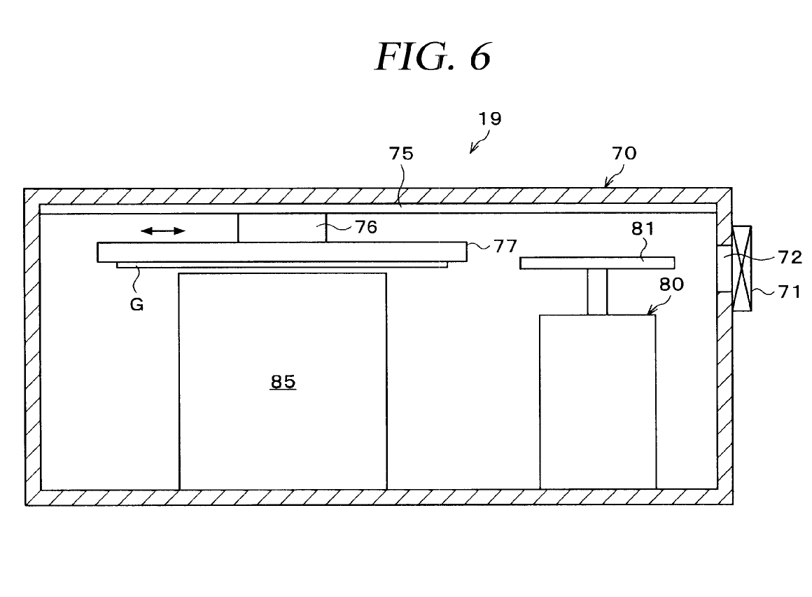

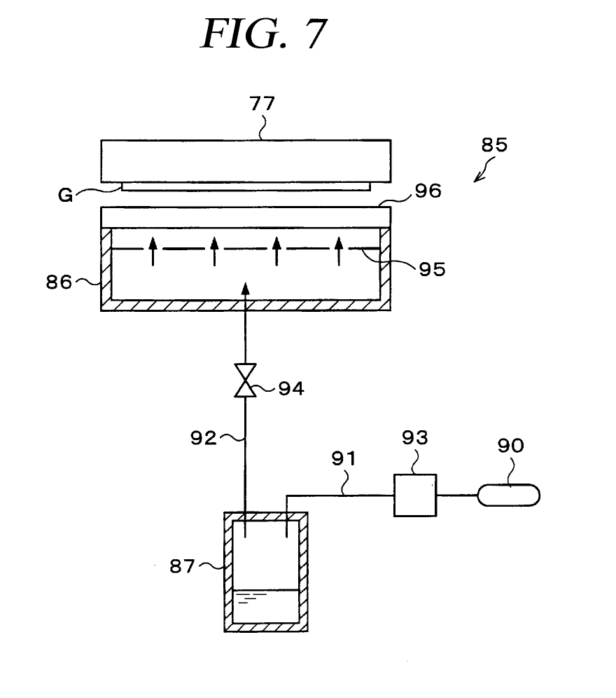

FIG. 6 shows a schematic view of the structure for the evaporating apparatus 19 as the deposition apparatus for forming the third layer. FIG. 7 shows a schematic drawing of the evaporating mechanism 85 disposed in the evaporating apparatus 19. In the present invention, the evaporating mechanism 85 disposed in the evaporating apparatus 19 corresponds to a third deposition mechanism for forming the light emitting layer 2 as the third layer (including the hole transport layer, etc.).

At the side of a processing chamber 70 constituting the evaporating apparatus 19, equipped is a transfer opening 72 opened and closed by a gate valve 71, through which the substrate G is transferred to the evaporating apparatus 19 by aforementioned transfer mechanism 20 in the transfer apparatus 11.

At the top portion of the processing chamber 70, there are provided a guide member 75 and a holding member 76 which moves along the guide member 75 by a suitable actuator (not shown). On the holding member 76, a substrate holding member 77 such as an electrostatic chuck is provided and the substrate G is held on the lower surface of the substrate holding member 77 horizontally.

In addition, provided is an alignment mechanism 80 between the transfer opening 72 and the substrate holding member 77. The alignment mechanism 80 has a stage 81 for aligning the substrate, and the substrate G transferred into the processing chamber 70 through the transfer opening 72 is at first held on the stage 81. After the alignment is completed, the stage 81 moves upward, and the substrate G is transferred to the substrate holding member 77.

Inside of the processing chamber 70, the evaporating mechanism 85 as the third deposition mechanism is disposed at the opposite side of the transfer opening 72 and the alignment mechanism 80 is disposed therebetween. As shown in FIG. 7, the evaporating mechanism 85 includes a deposition unit 86 underneath the substrate G held on the substrate holding member 77 and an evaporating unit 87 which accommodates the evaporating material for the light emitting layer 2. The evaporating unit 87 has a heater (not shown), and vapor of the evaporating material for the light emitting layer 2 is generated in the evaporating unit 87 by heat generated with the heater.

Connected to the evaporating unit 87 are a carrier gas introducing line 91 for introducing a carrier gas from a supply source 90 and a supply line 92 for supplying the vapor of the evaporating material for the light emitting layer 2 generated in the evaporating unit 87 together with the carrier gas to the deposition unit 86. There is provided a flow valve 93 to control the amount of the carrier gas flowing into the evaporating unit 87 on the carrier gas introducing line 91. A normal open valve 94 is provided on the supply line 92, which may be closed when, for example, replenishing the evaporating material of the light emitting layer 2 in the evaporating unit 87.

Inside of the deposition unit 86, a diffusion member is provided to diffuse the vapor of the evaporating material for the light emitting layer 2 transported from the evaporating unit 87. Furthermore, on upper side of the deposition unit 86, a filter 96 is provided to face the lower surface of the substrate G.

In addition, the substrate load lock apparatus 12 depicted in FIG. 2 is used for transferring the substrate G into/out of the deposition system 10, in a state where the interior atmosphere of the deposition system 10 is separated from the outside. The alignment apparatus 14 aligns the substrate G or the substrate G and mask M, and is provided for the apparatus, for example, the CVD apparatus 17 having no alignment mechanism. The shape forming apparatus 15 is used for forming the light emitting layer 2 formed on the substrate G into a desired shape. In the mask load lock apparatus 16, a mask is transferred into/out of the deposition system 10 in a state where the interior atmosphere of the deposition system 10 is separated from the outside. The CVD apparatus 17 is utilized for forming the sealing film 6 made of a nitride film or the like by the CVD to encapsulate the organic luminescent device A. The substrate reverse apparatus 18 appropriately reverses the substrate G to change the surface orientation, so that the surface (deposition surface) of the substrate G is oriented along the opposite direction of a gravitational force or is oriented along the direction of the gravitational force. In the present embodiment, the film formation is carried out while the substrate G's surface is facing downward in the evaporating apparatus 19, and the processes are performed while the substrate G's surface faces upward in the sputtering-evaporating apparatus 13, the shape forming apparatus 15 and the CVD apparatus 17. Therefore, the transfer apparatus 11 transfers the substrate G into the substrate reverse apparatus 18 and changes the surface orientation if necessary, while transferring it among apparatuses.

Now, in the deposition system 10 configured as above, the substrate G transferred via the substrate load lock apparatus 12 is at first transferred into the evaporating apparatus 19 by the transfer mechanism 20 in the transfer apparatus 11. In this case, as explained in FIG. 1 (1), the anode layer 1 made of, for example, the ITO is preformed as a predetermined pattern on the substrate G's surface (deposition surface).

In the evaporating apparatus 19, after aligning the substrate G in the alignment mechanism 80, it is held on the substrate holding member 77 while the substrate G's surface is faced downward. Then, in the evaporating mechanism 85 disposed in the processing chamber 70 of the evaporating apparatus 19, the vapor of the evaporating material for the light emitting layer 2 supplied from the evaporating unit 87 is emitted to the target surface of the substrate G (surface of the anode layer 1) from the deposition unit 86. Accordingly, as explained in FIG. 1 (2), the light emitting layer 3 (including the hole transport layer, etc.) as the third layer is deposited on the target surface of the substrate G.

The substrate G with the light emitting layer 2 formed in the evaporating apparatus 19 is then transferred by the transfer mechanism 20 in the transfer apparatus 11 to the sputtering-evaporating apparatus 13. And, in the sputtering-evaporating apparatus 13, the substrate G is held on the stage 42 after the mask is aligned. Further, the mask is transferred into the deposition system 10 via the mask load lock apparatus 16, and then transferred to the sputtering-evaporating apparatus 13 by the transfer mechanism 20 in the transfer apparatus 11.

Thereafter, the transfer mechanism 40 equipped in the sputtering-evaporating apparatus 13 transfers the substrate G held on the stage 42 to below the evaporating mechanism 35. Then, by the evaporating mechanism 35, as explained in FIG. 1 (3), the work function adjustment layer 3 as the first layer is vapor deposited on the target surface of the substrate G (surface of the light emitting layer 2) to form a predetermined pattern.

Next, the substrate G held on the stage 42 is transferred to below the sputtering mechanism 36. After that, as described in FIG. 1 (4), the cathode layer 4 as the second layer is formed on the surface of the substrate G (surface of the work function adjustment layer 3) to form a predetermined pattern by the sputtering mechanism 36.

When the work function adjustment layer 3 and the cathode layer 4 are formed in the sputtering-evaporating apparatus 13, the processing chamber 30 is evacuated through the exhaust line 31.

In this way, the substrate G formed with the work function adjustment layer 3 and the cathode layer 4 in the sputtering mechanism 36 is then transferred into the shape forming apparatus 15 by the transfer mechanism 20 of the transfer apparatus 11. Then, in the shape forming apparatus 15, as explained in FIG. 1 (5), the light emitting layer 2 is formed into a predetermined shape corresponding to the cathode layer 4.

The substrate G having the light emitting layer 2 shaped in the shape forming apparatus 15 is again transferred into the sputtering-evaporating apparatus 13 to form the connection portion 4′ relating to the electrode 5, as described in FIG. 1 (6).

After that, the substrate G is transferred into the CVD apparatus 17 by the transfer mechanism 20 of the transfer apparatus 11, and as described in FIG. 1 (7), the OEL device A with the light emitting layer 2 sandwiched by the cathode layer 4 and the anode layer 1 is encapsulated with the sealing film 6, for example, a nitride film. Thus, the organic electroluminescent device A (substrate G) is transferred out of the deposition system 10 via the substrate load lock apparatus 12.

In the aforementioned deposition system 10, since the evaporating mechanism 35 for the work function adjustment layer 3 as the first deposition mechanism is disposed in the process chamber 30 which is different from where the evaporating mechanism 85 as the third deposition mechanism for the light emitting layer 2 is disposed, contamination originating from the adhesive alkali metal, such as lithium, is prevented when forming the light emitting layer 2, and it can be possible to produce the excellent organic EL device A with good light emitting efficiency. In addition, in the evaporating apparatus 19, contamination due to metal mask contact is avoided because a pattern mask is not used when forming the light emitting layer 2.

Further, since the sputtering-evaporating apparatus includes the evaporating mechanism 35 as the first deposition mechanism and the sputtering mechanism 36 as the second deposition mechanism, it is possible to manufacture the deposition system 10 to have a small size. Furthermore, the work function adjustment layer 3 as the first layer and the cathode layer 4 as the second layer can be successively formed in the same sputtering mechanism 36 so that throughput can be improved. Moreover, since the cathode layer 4 can be quickly formed right after the work function adjustment layer 3 is formed, the work function adjustment layer 3 can be prevented from being deteriorated.

Furthermore, in the evaporating mechanism 35 serving as the first deposition mechanism, the vapor generator 45 generating the vapor of the deposition material is disposed outside of the processing chamber 30 of the sputtering-evaporating apparatus 13, so that the vapor of the deposition material generated from the vapor generator 45 can be prevented from being transported into the processing chamber 30 more than what is necessary. Further, by quickly depositing the vapor of the deposition material, which is supplied through the nozzle 34, on the substrate G, it is possible to prevent the inside of the processing chamber 30 from being contaminated by the alkali metal having a high reactivity such as Li or the like.

In addition, when supplementing the vapor generator 45 of the evaporating mechanism 35 with the material for the work function adjustment layer 3 (deposition material source), it is possible to supplement the heater 51 in the vapor generator 45 with the deposition material source while keeping the inside of the processing chamber 30 under the depressurized atmosphere by closing the opening/closing valve 58 installed on the line 46 communicating the processing chamber 30 with the chamber 50 and opening only the chamber 50 to the atmosphere. In this case, while carrying out the supplement work, it is also possible to prevent moisture or contaminant from being introduced into the processing chamber 30 from the atmosphere. Since the volume of the chamber 50 is smaller than that of the processing chamber 30, even if the chamber 50 is opened to the atmosphere, it can be immediately returned to the depressurized condition by evacuation of the vacuum pump 57. In this manner, by opening the opening/closing valve 58 after depressurizing and evacuating the inside of the chamber 50, it is possible to immediately resume the deposition process in the processing chamber 30 so that work efficiency can be improved.

Further, in the sputtering mechanism 36 serving as the second deposition mechanism, the cathode layer 4 as the second layer is formed on the substrate G by the sputtering so that the scale up of the substrate G can be possible and thus a uniform deposition may be achieved in comparison with the evaporating. Furthermore, as shown in FIG. 1 (7), by encapsulating the substrate G with the sealing film 6 such as a nitride film, it is possible to manufacture the organic EL device A having a superior sealing ability and a good durability.

Hereinbefore, although the favorable embodiment of the present invention has been explained, the present invention is not limited to the embodiment described in the drawings. It would be understood by those skilled in the art that various changes and modifications may be made within the scope of the appended claims. Therefore, they should be construed as being included therein. Though, for example, the present invention has been explained referring to the manufacturing process of the organic electroluminescent device A, the present invention can also be applied to film formations of other electronic devices. In addition, in the manufacturing process of the organic electroluminescent device A, though the work function adjustment layer 3, the cathode layer 4 and the light emitting layer 2 have been explained as the first layer, the second layer and the third layer, respectively, these first layer through third layer are not limited to the work function adjustment layer 3, the cathode layer 4 and the light emitting layer 2. Further, the first deposition mechanism through the third deposition mechanism can be the evaporating mechanism, the sputtering mechanism, the CVD mechanism or other deposition mechanisms. In FIG. 2, one example of the deposition system 10 is shown, but combination of the apparatuses can be changed appropriately.

### INDUSTRIAL APPLICABILITY

The present invention can be applied to the manufacturing field of, for example, an organic electroluminescent device.

What is claimed is:

1. A deposition apparatus for forming a film on a substrate, the apparatus comprising:
a first deposition mechanism for forming a first layer in a processing chamber;
a second deposition mechanism for forming a second layer in the processing chamber; and
a transfer mechanism for transferring the substrate to each processing position of the first deposition mechanism and the second deposition mechanism in the processing chamber,
wherein the first deposition mechanism includes:
a nozzle which is disposed at an inside of the processing chamber, for supplying vapor of a deposition material to the substrate;
a vapor generator which is disposed at an outside of the processing chamber, for generating the vapor of the deposition material; and
a line for transporting the vapor of the deposition material generated from the vapor generator to the nozzle, and
the second deposition mechanism forms the second layer by a sputtering method.

2. The deposition apparatus of claim 1, wherein the vapor generator has:
a chamber disposed at the outside of the processing chamber; and
a heating device for heating a deposition material source in the chamber.

3. The deposition apparatus of claim 2, wherein the vapor of the deposition material is transported to the nozzle from the vapor generator by using a carrier gas.

4. The deposition apparatus of claim 3, wherein the chamber is allowed to be opened and closed.

5. The deposition apparatus of claim 2, further comprising:
a vacuum pump for evacuating the inside of the processing chamber to a reduced pressure;
a vacuum pump for evacuating an inside of the chamber to a reduced pressure; and
an opening/closing mechanism for opening and closing the line.

6. The deposition apparatus of claim 5, wherein a volume of the chamber is smaller than that of the processing chamber.

7. The deposition apparatus of claim 1,
wherein the vapor generator of the first deposition mechanism generates vapor of alkali metal.

8. The deposition apparatus of claim 1, wherein the vapor generator of the first deposition mechanism generates vapor of Li.

9. A deposition system for forming a film on a substrate, the system comprising:
a deposition apparatus as claimed in claim 1; and
a separate deposition apparatus having a third deposition mechanism for forming a third layer in a processing chamber.

10. The deposition system of claim 9, further comprising:
a transfer apparatus which transfers the substrate between the deposition apparatus and the separate deposition apparatus.

11. The deposition system of claim 9, wherein the third deposition mechanism forms the third layer on a surface of the substrate by an evaporation method.

12. A deposition method for forming a film on a substrate, the method comprising:
transferring the substrate to a processing position of a first deposition mechanism in a processing chamber;
by using the first deposition mechanism, forming a first layer by supplying vapor of a deposition material, which is generated at an outside of the processing chamber, to the substrate through a nozzle disposed at an inside of the processing chamber;
subsequently, transferring the substrate to a processing position of a second deposition mechanism; and
by using the second deposition mechanism, forming a second layer by a sputtering method.

13. (canceled)

14. The deposition method of claim 12, wherein a third layer is preformed at an inside of a separate processing chamber.

15. The deposition method of claim 14, wherein the third layer is formed by an evaporating method.

16. The deposition apparatus of claim 1, wherein the substrate is held so that its deposition surface is faced up.
